(19) United States
(12) Patent Application Publication
(10) Pub. No.: US 2008/0121264 A1
(43) Pub. Date: May 29, 2008

(54) THIN FILM SOLAR MODULE AND METHOD OF FABRICATING THE SAME

(75) Inventors: Chi-Lin CHEN, Hsinchu City (TW); Jian-Shu WU, Beigang Town (TW)

Correspondence Address: Akin Gump LLP - Silicon Valley, 3000 El Camino Real, Two Palo Alto Square, Suite 400, Palo Alto, CA, 94306, US

(73) Assignee: INDUSTRIAL TECHNOLOGY RESEARCH INSTITUTE, Hsinchu (TW)

(21) Appl. No.: 11/563,781

(22) Filed: Nov. 28, 2006

(51) Int. Cl. H01L 31/042

(52) U.S. Cl. 136/244; 438/73; 257/E31.001

(57) ABSTRACT

A device capable of converting solar radiation into electrical energy includes a substrate, and a plurality of cells formed over the substrate extending in parallel to each other, each of the plurality of cells including at least one thin film layer and having a size dependent on a film thickness distribution of a machine capable of forming the at least one thin film layer.

### BACKGROUND OF THE INVENTION

The present invention relates generally to a solar cell and, more particularly, to a thin film solar module and a method of fabricating the thin film solar module.

Solar energy is one of the most important energy sources that have become available in recent years. A great deal of attention has been paid to photovoltaic devices, i.e., solar cells, which are capable of converting solar radiation into electrical energy based on the photovoltaic effect. Solar cells, powered by the virtually limitless energy of the sun, need not be replenished with fossil fuels and therefore have been applied to satellites, space and mobile communications. In view of the increasing demands for energy saving, effective utilization of resources and prevention of environmental pollution, a solar cell has become an attractive device for generating energy.

Solar cells may be fabricated on silicon (Sᵢ) wafers. However, the cost of electricity generated using water-type solar cells is relatively high as compared to electricity generated by the traditional methods, such as fossil-fuel-burning power plants. To make solar cells more economically viable, low-cost, thin-film growth techniques that deposit high-quality light-absorbing semiconductor materials have been developed. These thin-film approaches grow solar cells or solar cell modules on large-area substrates, which advantageously achieve cost-effective fabrication and allow versatile modular designs. However, the thin-film approaches may suffer from deviation in film thickness, across a large-area substrate and may disadvantageously result in undesirable electrical characteristics.

FIG. 1 is a schematic diagram illustrating film thickness ratio relative to cell position. The film thickness ratio refers to a ratio of thickness of a semiconductor film at a certain position to a maximum thickness of the semiconductor film at a position along, for example, a length direction of a substrate over which the semiconductor film is deposited. The semiconductor film is often formed in a reaction chamber of a chemical vapor deposition (“CVD”) machine. Since reaction gases may generally be not uniformly distributed in the reaction chamber, the semiconductor film is not uniformly formed over the substrate and therefore exhibits film thickness deviation, which may reach 20% off the maximum thickness. Referring to FIG. 1A, for the purpose of simplicity, the film thickness ratio at different positions along a length direction of a substrate is plotted in a curve. However, skilled persons in the art will understand that an actual semiconductor film thickness distribution or surface topology is more complicated than what the schematic curve illustrated in FIG. 1A may represent.

FIG. 1B is a schematic diagram of a top view of a conventional solar module 10. Referring to FIG. 1B, the solar module 10 includes a plurality of cells 12-1 formed on substrate 11. The plurality of cells 12-1, each having a width “w” and a length “L”′, are electrically connected in series with each other. Ideally, without film thickness distribution, each of the plurality of cells 12-1 provides an open-circuit voltage (V_{OC}) of approximately 1.4 V (volts), and a short-circuited current density (J_{SC}) of approximately 13 milliampere per square centimeter (mA/cm²). Given a w and L′ being 1 cm and 50 cm, respectively, an ideal solar cell provides an electric current of approximately 0.65 A. Since the ideal solar cells are connected in series, an ideal solar module provides a voltage of 14 V (=1.4 V×10) and a current of 0.65 A. In an actual implementation, however, due to film thickness distribution, the short-circuit current density may be different from cell to cell. As illustrated, the respective short-circuit current density of the cells corresponding to film thickness ratios of 1, 0.95, 0.9, 0.85 and 0.8 is 13, 12.4, 11.7, 11.1 and 10.4 (mA/cm²). Furthermore, the respective current provided by the cells is 0.65, 0.62, 0.59, 0.56 and 0.52 (A). Consequently, the solar module 10 provides a voltage of 14 V and a current of 0.52 A, which disadvantageously results in a 20% reduction in conversion efficiency as compared to the ideal solar module.

Accordingly, it is desirable to have a solar module that is able to take advantage of the film thickness distribution in order to improve conversion efficiency. It is also desirable to have a method of fabricating such a solar module.

### BRIEF SUMMARY OF THE INVENTION

Examples of the invention may provide a device capable of converting solar radiation into electrical energy that comprises a substrate, and a plurality of cells formed over the substrate, each of the plurality of cells including at least one thin film layer and having a size dependent on a film thickness distribution of a machine capable of forming the at least one thin film layer.

Examples of the invention may also provide a device capable of converting solar radiation into electrical energy that comprises a substrate, and a number of N cells formed over the substrate having respective widths W₁ to W_{N}, N being an integer, each of the widths W₁ to W_{N} being substantially inversely proportional to a corresponding one of film thickness ratios R₁ to R_{N}, where the film thickness ratios R₁ to R_{N} are determined in accordance with a film thickness distribution of a machine capable of forming at least one thin film layer over the number of N cells.

Some examples of the invention may also provide a method of fabricating a device capable of converting solar radiation into electrical energy, the method comprising providing a substrate, forming a first set of cells on the substrate including forming at least one thin film layer of the plurality of cells in a machine capable of thin film deposition, obtaining information on film thickness distribution over the substrate from the machine, determining a set of film thickness ratios corresponding to the plurality of cells in accordance with the film thickness distribution; and forming a second set of cells in accordance with the set of film thickness ratios such that each of the second set of cells includes a width substantially inversely proportional to a corresponding one of the set of film thickness ratios.

It is to be understood that both the foregoing general description and the following detailed description are exemplary and explanatory only and are not restrictive of the invention, as claimed.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings examples consistent with the invention. It should be understood, however, that the invention is not limited to the precise arrangements and instrumentalities shown.

In the drawings:

FIG. 1A is a schematic diagram illustrating film thickness ratio relative to cell position;

FIG. 1B is a schematic diagram of a top view of a conventional solar module;

FIG. 2 is a schematic diagram of a top view of a solar module consistent with an example of the present invention;

FIG. 3 is a flow diagram illustrating a method of fabricating a solar module consistent with an example of the present invention; and

FIGS. 4A to 4F are schematic cross-sectional view illustrating a method of fabricating a solar module consistent with an example of the present invention.

### DETAILED DESCRIPTION OF THE INVENTION

Reference will now be made in detail to the present embodiments of the invention, examples of which are illustrated in the accompanying drawings. Wherever possible, the same reference numbers will be used throughout the drawings to refer to the same or like portions.

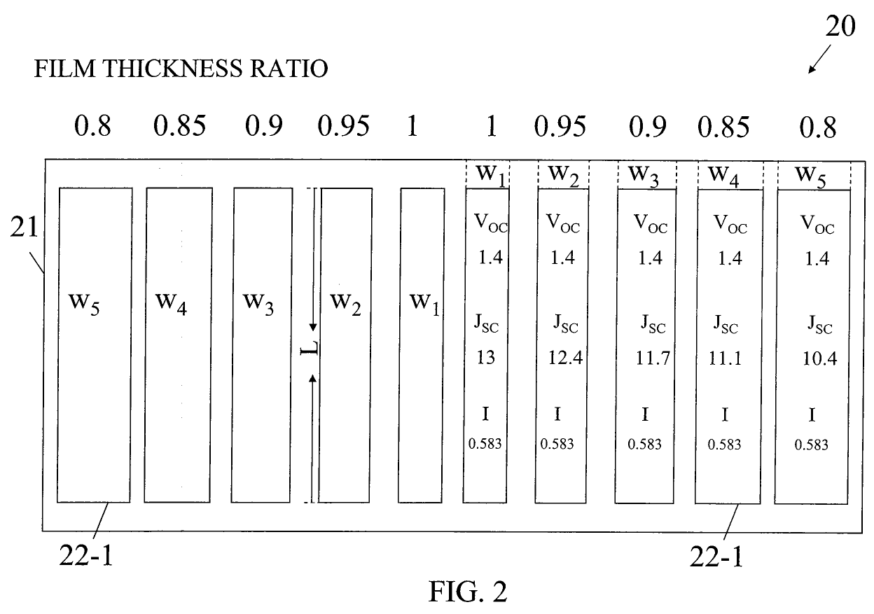

FIG. 2 is a schematic diagram of a top view of a solar module 20 consistent with an example of the present invention. Referring to FIG. 2, the solar module 20 includes a plurality of solar cells 22-1 formed on a substrate 21. In the present example, the solar cells 22-1 are electrically connected together in series. In other examples, however, the solar cells 22-1 may be electrically connected in parallel, or in a series-parallel combination. The desired output voltage and current, at least in part, determine the number of solar cells in a solar module and the solar cell array topology.

In one example, the substrate 21 has a dimension of approximately 52 cm×11 cm, and each of the plurality of cells 22-1 has a length “L” of approximately 50 cm. The respective width of each of the plurality of cells 22-1, however, is dependent on the film thickness ratio. Specifically, the greater the film thickness ratio corresponding to one of the plurality of cells 22-1, the smaller the width of the one cell 22-1, which will be discussed in detail below.

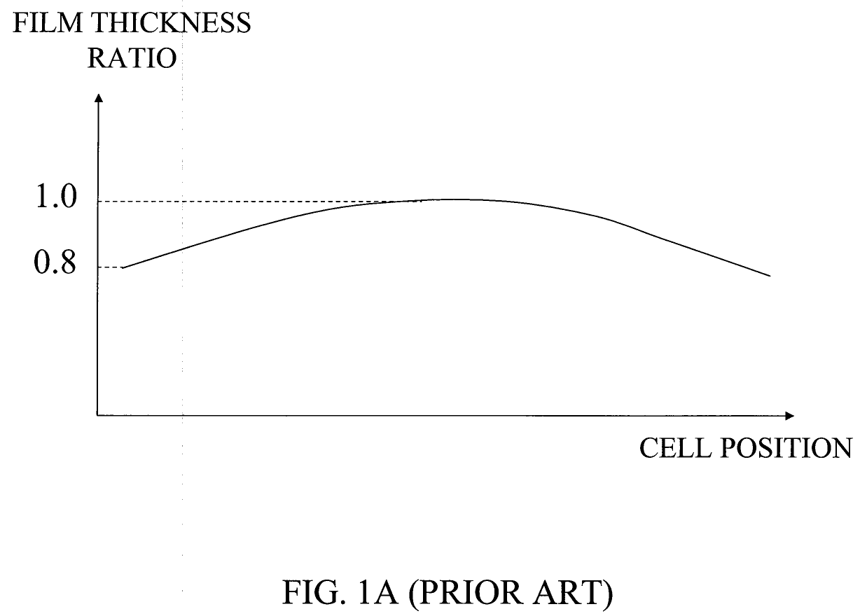

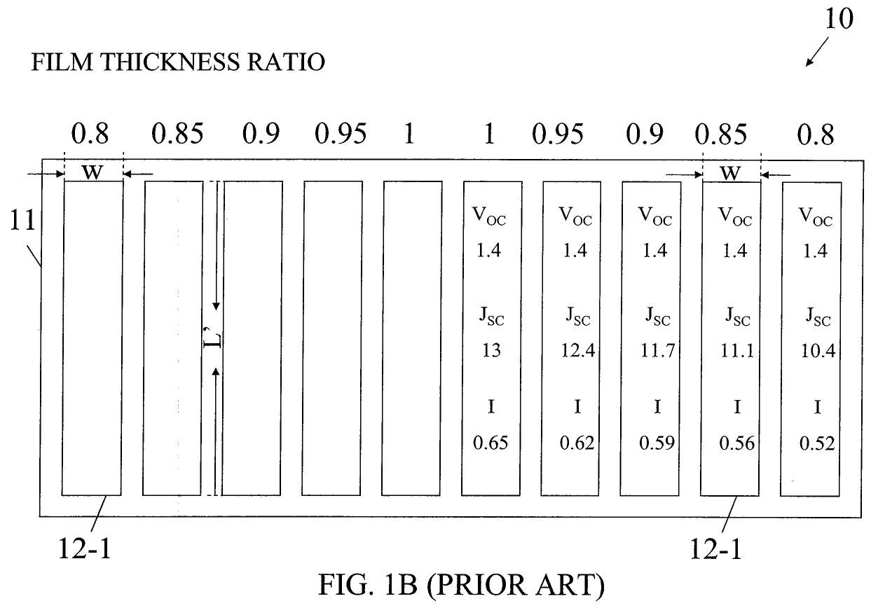

For the purpose of illustration, the same film thickness distribution illustrated in FIG. 1A and the same set of film thickness ratio and in turn the short-circuit current density illustrated in FIG. 1B are used in the present example. For machines capable of thin film deposition in the fabrication of large-size solar modules, the film thickness distribution may generally be different from machine to machine but may substantially remain the same in an individual machine. Therefore, information on the film thickness distribution is accessible from a machine after fabricating solar modules for a predetermined period, for example, one day or a week. Consequently, the film thickness ratio and the short-circuit current density can be determined. As previously discussed, the current density at a cell region is substantially directly proportional to the amount of film deposited on the cell region and in turn the film thickness ratio corresponding to the cell region. By taking advantage of the machine property in providing substantially the same film distribution pattern in an individual machine, the size of each of the cells 22-1 is optimized so that the solar module 20 is able to generate an optimal current. After the length L of each of the cells 22-1 is determined, that is, 50 cm in the present example, the width of each of the cells 22-1 is calculated below.

w₅+w₄+w₃+w₂+w₁+w₁+w₂+w₃+w₄w₅=10×1 (cm) (Equation 1)

given that an ideal cell width for the substrate 21 without film thickness distribution is one (1) centimeter and the solar module 20 includes ten (10) cells 22-1. The width of an ideal cell may be determined by dividing the length of a substrate region available for cell fabrication by the number of cells predetermined for fabrication.

Furthermore, as previously discussed, since the optimal width of a cell is inversely proportional to the film thickness ratio corresponding to the cell region, the above Equation 1 may be rewritten as follows.

(w₁/0.8)+(w₁/0.85)+(w₁/0.9)+(w₁/0.95)+(w₁/1)+(w₁/1)+(w₁/0.95)+(w₁/0.9)+(w₁/0.85)+(w₁/0.8)=10 (cm) (Equation 2)

The width of the cell 22-1 corresponding to the film thickness ratio 1, i.e., w₁, can then be determined. The other widths w₂, w₃, w₄ and w₅, which respectively equal (w₁/0.95), (w₁/0.9), (w₁/0.85) and (w₁0.8), are also determined. In the present example, w₁, w₂, w₃, w₄ and w₅ are 0.896, 0.943, 0.995, 1.05 and 1.12 (cm), respectively. As an example of the cell 22-1 having the width w₁, the current provided is approximately 0.583 A (=13×0.896×50). Furthermore, the current provided by the cell 22-1 having the width w₂ is also approximately 0.583 A (=12.4×0.943×50). Accordingly, each of the cells 22-1 provides substantially the same current output of 0.583 A because in each of the cells 22-1 the product of the respective optimal width and the corresponding short-circuit current density is a same constant. A comparison among the ideal solar module, the conventional solar module 10 illustrated in FIG. 1B and the solar module 20 is summarized in Table 1 below.

TABLE 1

| | output | | | | |
|---|---|---|---|---|---|
| | | | FF | | |
| module | V_{OC} (V) | I_{SC} (A) | (Fill Factor) | W_{P} (W) | η (%) |
| Ideal module | 14 | 0.65 | 0.71 | 6.46 | 12.92 |
| Solar module 10 | 14 | 0.52 | 0.71 | 5.16 | 10.32 |
| Solar module 20 | 14 | 0.583 | 0.71 | 5.79 | 11.58 |

where the fill factor (FF) refers to the ratio of a maximum power (Wₚ) divided by the open-circuit voltage (V_{OC}) and the short-circuit current (I_{SC}), and the symbol “η” represents a solar module's energy conversion efficiency, which is the percentage of power converted from absorbed sun light to electric energy and power collected. The solar module 20 has a greater current output and an improved conversion efficiency than those of the conventional solar module 10 illustrated in FIG. 1B.

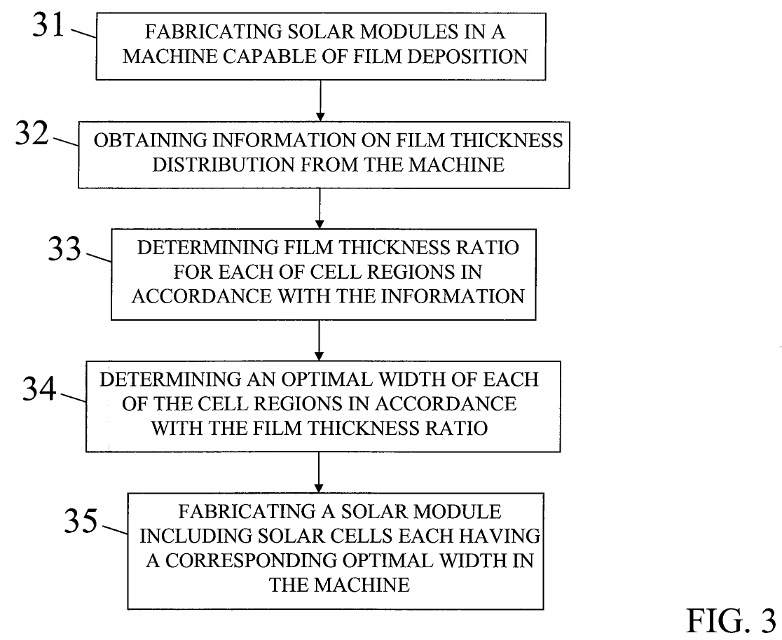

FIG. 3 is a flow diagram illustrating a method of fabricating a solar module consistent with an example of the present invention. Referring to FIG. 3, at step 31, a batch of solar modules each including a plurality of solar cells are fabricated in a machine capable of thin film deposition such as a chemical vapor deposition (“CVD”) machine including one of a plasma-enhanced CVD (“PECVD”) and a radio-frequency (“RF”) PECVD machine. Each of solar cells has substantially the same length and width. Next, at step 32, information regarding film thickness distribution is collected. At step 33, film thickness ratio and short-circuit current density corresponding each of cell regions may be calculated in accordance with the information. Next, at step 34, an optimal width of each of the cell regions is determined in accordance with the film thickness ratio. At step 35, another batch of solar modules are fabricated in the machine, each of the solar cells in the solar modules has an optimal width so that the product of the optimal width and the corresponding short-current density is substantially the same among the solar cells.

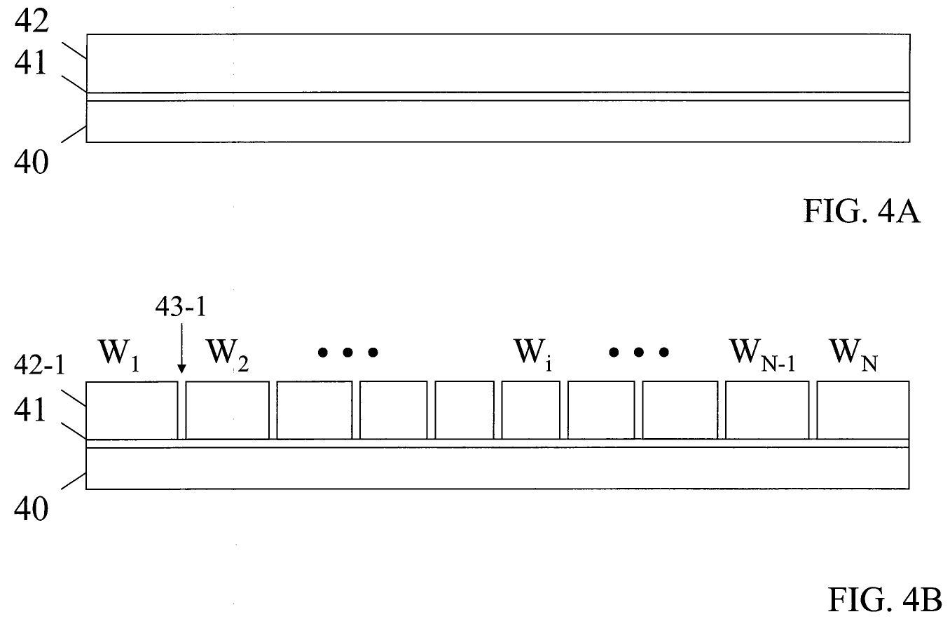

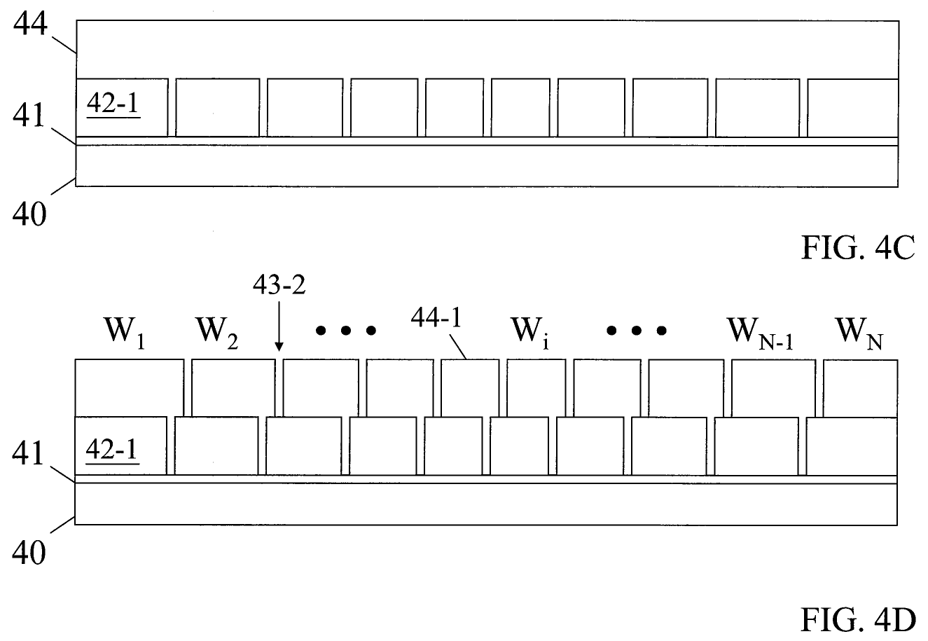

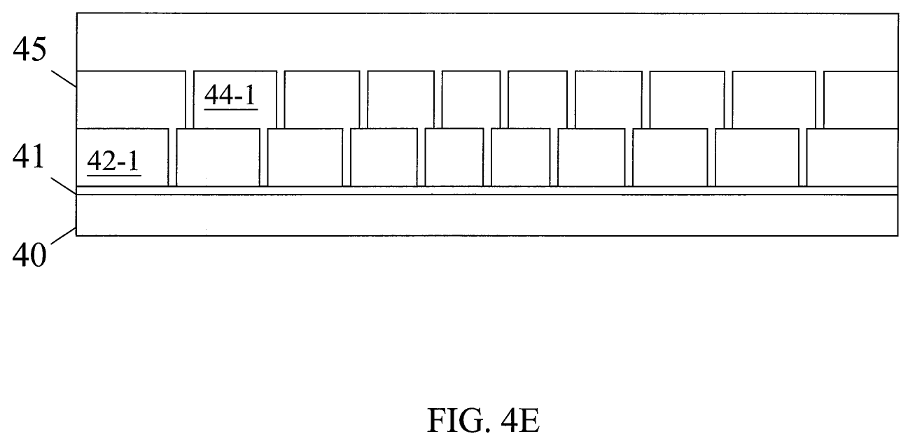

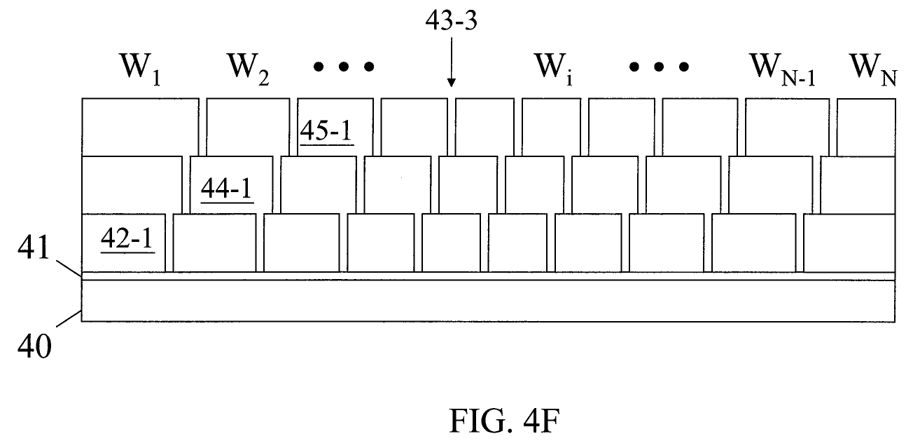

FIGS. 4A to 4F are cross-sectional views illustrating a method of fabricating a solar module consistent with an example of the present invention. Referring to FIG. 4A, a substrate 40 is provided. The substrate 40 includes a transparent substrate made of glass or an opaque substrate made of plastic, metal or ceramic. The length and width of the substrate 40 depend on application's need and may rang from approximately 50 centimeter (cm) to 200 cm. The thickness of the substrate 40 ranges from approximately 1 millimeter (mm) to 4 mm. Nevertheless, the dimensions of the substrate 40 are only exemplary and may vary in particular applications.

Next, an insulating layer 41 such as a silicon oxide layer is formed on the substrate 40 by, for example, a conventional chemical vapor deposition (“CVD”) process or other suitable process. The insulating layer 41 may alleviate the surface unevenness of the substrate 40 so as to facilitate the formation of subsequent layers. Furthermore, the insulating layer 41 may function to serve as a buffer or diffusion barrier layer to prevent undesired ions or particles in the substrate 40 from contaminating a subsequent layer. In one example according to the present invention, in the case of a glass substrate, the thickness of the insulating layer 41 is approximately 20 to 300 nanometer (nm) and, in the case of a plastic, metal or ceramic substrate, the thickness of the insulating layer 41 is approximately 50 to 500 nm.

Next, a bottom electrode layer 42 is formed on the insulating layer 41 by, or example, a conventional sputtering, evaporating, physical vapor deposition (“PVD”) process or other suitable process. Suitable materials for the bottom electrode layer 42 include but are not limited to transparent conductive oxide (“TCO”) such as indium tin oxide (“ITO”), tin oxide (“SnO2”) or zinc oxide (“ZnO”) in the case of a transparent substrate, or a conductive metal such as aluminum (Al), silver (Ag) or molybdenum (Mo) in the case of an opaque substrate. The thickness of a TCO layer ranges from approximately 300 nm to 1000 nm, while the thickness of an Al or Ag layer ranges from approximately 200 nm to 2000 nm but could vary in particular applications.

Referring to FIG. 4B, respective bottom electrodes 42-1 are formed by scribing the bottom electrode layer 42 by, for example, a conventional laser scribing process or other suitable process. Suitable laser sources may include a yttrium aluminum garnet (Nd:YAG) laser, a pulsed ytterbium fiber (Nd:YLP) laser, carbon dioxide laser or other suitable optical energy device known in the art. The laser scribing process leaves a plurality of first grooves 43-1, which expose portions of the insulating layer 41 and separate the bottom electrodes 42-1 from each other at an interval of approximately 50 micrometer (μm) to 100 μm. Each of the bottom electrodes 42-1 has a same length and a width approximately inversely proportional to a corresponding current density, which in turn is approximately directly proportional to the film thickness ratio. The respective width of the bottom electrodes 42-1, i.e., W₁ to W_{N}, which may be determined in accordance with a method illustrated in FIG. 3, is calculated as follows.

W₁+W₂+. . . , +Wᵢ+. . . +W_{N-1}W_{N}=N×W₀ (Equation 3)

where Wᵢ is the optimal width of a cell region having the maximum film thickness ratio, i.e., 1, N is the number of cells in a solar module, and W₀ is the width of an ideal cell. The above Equation 3 can be rewritten as follows.

Wᵢ(1/r₁+1/r₂+. . . +1+. . .+1/r_{N-1}+1/r_{N})=N×W₀ (Equation 4)

where r₁ to r_{N} are film thickness ratios correspond to the respective cell regions.

Referring to FIG. 4C, a semiconductor layer 44 including photoelectric conversion material is formed over the bottom electrodes 42-1 by, for example, a conventional PECVD, RF PECVD process or other suitable process. The semiconductor layer 44 of the cells may include a single junction (p-i-n or n-i-p), double junction (p-i-n/p-i-n or n-i-p/n-i-p) or multi-junction structure, wherein the p, i and n refer to a p-type, an intrinsic an dan n-type layer, respectively. The thickness of the semiconductor layer 44 ranges from approximately 200 nm to 2 μm. Suitable photoelectric conversion materials include silicon, copper-indium diselenide (CulnSe₂, “CIS”), copper-indium gallium diselenide (CulnGaSe₂, “CIGS”), dye-sensitized solar cell (“DSC”) structures including an inorganic wide band-gap semiconductor (TiO₂) coated by a ruthenium polypyridyl complex, and organic semiconductors such as polymers and small-molecule compounds like polyphenylene vinylene, copper phthalocyanine and carbon fullerenes.

Referring to FIG. 4D, respective semiconductor structures 44-1 are formed by scribing the semiconductor layer 44 by, for example, a second laser scribing process. The semiconductor structures 44-1 are separated from each other by a plurality of second grooves 43-2 each having a width of approximately 50 μm to 100 μm. The second grooves 43-2 are offset from the first grooves 43-1 by one groove width to ensure isolation between the bottom electrodes 42-1 and the semiconductor structures 44-1. The respective width of the semiconductor structures 44-1, i.e., W₁ to W_{N}, is the same as that of the corresponding bottom electrodes 42-1.

Referring to FIG. 4E, a top electrode layer 45 is formed over the semiconductor structures 44-1 by, for example, a conventional sputtering, evaporating, PVD process or other suitable process. Suitable materials for the top electrode layer 45 include but are not limited to a conductive metal such as aluminum (Al) or silver (Ag) in the case of an opaque substrate, or transparent conductive oxide (“TCO”) such as indium tin oxide (“ITO”), tin oxide (“SnO2”) or zinc oxide (“ZnO”) in the case of a transparent substrate. The thickness of an Al or Ag layer ranges from approximately 200 nm to 1000 nm, while the thickness of a TCO layer ranges from approximately 100 nm to 1000 nm.

Next, referring to FIG. 4F, respective top electrodes 45-1 are formed by scribing the top electrode layer 45 by, for example, a conventional laser scribing process. The top electrodes 45-1 are separated from each other by a plurality of third grooves 43-3 each having a width of approximately 50 μm to 100 μm. The third grooves 43-2 are offset from the second grooves 43-2 by one groove width to ensure isolation between the top electrodes 45-1 and the semiconductor structures 44-1. The respective width of the top electrodes 45-1, i.e., W₁ to W_{N}, is the same as that of the corresponding bottom electrodes 42-1. For the purpose of simplicity, the sidewalls of the layers 40, 41, 42, 44 and 45 as illustrated in the FIGS. 4A to 4F are flush with each other. However, skilled person in the art will understand that the sidewall condition may be different in particular applications and may be dependent on the structure of a module or the electrical connection between cells of a module.

It will be appreciated by those skilled in the art that changes could be made to one or more of the examples described above without departing from the broad inventive concept thereof. It is understood, therefore, that this invention is not limited to the particular examples disclosed, but it is intended to cover modifications within the scope of the present invention as defined by the appended claims.

Further, in describing certain illustrative examples of the present invention, the specification may have presented the method and/or process of the present invention as a particular sequence of steps. However, to the extent that the method or process does not rely on the particular order of steps set forth herein, the method or process should not be limited to the particular sequence of steps described. As one or ordinary skill in the art would appreciate, other sequences of steps may be possible. Therefore, the particular order of the steps set forth in the specification should not be construed as limitations on the claims. In addition, the claims directed to the method and/or process of the invention should not be limited to the performance of their steps in the order written, and one skilled in the art can readily appreciate that the sequences may be varied and still remain within the spirit and scope of the present invention.

We claim:

1. A device capable of converting solar radiation into electrical energy, comprising:
a substrate; and
a plurality of cells formed over the substrate, each of the plurality of cells including at least one thin film layer and having a size dependent on a film thickness distribution of a machine capable of forming the at least one thin film layer.

2. The device of claim 1, wherein each of the plurality of cells has a width substantially inversely proportional to a film thickness ratio corresponding to the each cell, the film thickness ratio being obtainable from the film thickness distribution of the machine.

3. The device of claim 2, wherein the product of the width and the corresponding film thickness ratio of each of the plurality of cells is substantially the same.

4. The device of claim 1, wherein each of the plurality of cells has a width substantially inversely proportional to a short-circuit current density corresponding to the each cell, the short-circuit current density being obtainable from the film thickness distribution of the machine.

5. The device of claim 4, wherein the product of the width and the corresponding short-circuit current density of each of the plurality of cells is substantially the same.

6. The device of claim 1, wherein each of the plurality of cells includes an electrode layer, and the electrode layer has a width substantially inversely proportional to a film thickness ratio corresponding to the each cell, the film thickness ratio being obtainable from the film thickness distribution of the machine.

7. The device of claim 1, wherein each of the plurality of cells includes a semiconductor layer, and the semiconductor layer has a width substantially inversely proportional to a film thickness ratio corresponding to the each cell, the film thickness ratio being obtainable from the film thickness distribution of the machine.

8. The device of claim 1, wherein each of the plurality of cells includes a bottom electrode layer, a semiconductor layer and a top electrode layer, and wherein each of the bottom electrode layer, the semiconductor layer and the top electrode layer has a width substantially inversely proportional to a film thickness ratio corresponding to the each cell, the film thickness ratio being obtainable from the film thickness distribution of the machine.

9. The device of claim 1, wherein the substrate includes one of a glass substrate, a plastic substrate, a metal substrate and a ceramic substrate.

10. A device capable of converting solar radiation into electrical energy, comprising:
a substrate; and
a number of N cells formed over the substrate having respective widths Wᵢ to W_{N}, N being an integer, each of the widths Wᵢ to W_{N} being substantially inversely proportional to a corresponding one of film thickness ratios R₁ to R_{N}, where the film thickness ratios R₁ to R_{N} are determined in accordance with a film thickness distribution of a machine capable of forming at least one thin film layer over the number of N cells.

11. The device of claim 10, wherein each of the number of N cells includes an electrode layer having substantially the same width as the each cell.

12. The device of claim 10, wherein each of the number of N cells includes a semiconductor layer having substantially the same width as the each cell.

13. The device of claim 10, wherein the widths W₁ to W_{N} satisfy an equation:
W₁+W₂+. . . , +Wᵢ+. . . +W_{N-1}W_{N}=N×W₀
where Wᵢ is the width of one of the number of N cells having a maximum film thickness ratio, and W₀ is the width of a cell free from the concern of film thickness distribution.

14. The device of claim 13, wherein the widths W₁ to W_{N} and the film thickness ratios R₁ to R_{N} satisfy an equation:
Wᵢ(1/R₁+1/R₂+. . . +1+. . .+1/R_{N-1}+1/R_{N})=N×W₀
where Rᵢ equals 1, the maximum film thickness ratio, which corresponds to the width Wᵢ.

15. A method of fabricating a device capable of converting solar radiation into electrical energy, the method comprising:
providing a substrate;
forming a first set of cells on the substrate including forming at least one thin film layer of the plurality of cells in a machine capable of thin film deposition;
obtaining information on film thickness distribution over the substrate from the machine;
determining a set of film thickness ratios corresponding to the plurality of cells in accordance with the film thickness distribution; and
forming a second set of cells in accordance with the set of film thickness ratios such that each of the second set of cells includes a width substantially inversely proportional to a corresponding one of the set of film thickness ratios.

16. The method of claim 15, wherein the product of the width and the corresponding film thickness ratio of each of the second set of cells is substantially the same.

17. The method of claim 15, wherein each of the second set of cells includes an electrode layer, and the electrode layer as a width substantially inversely proportional to one of the set of film thickness ratios corresponding to the each cell.

18. The method of claim 15, wherein each of the second set of cells includes a semiconductor layer, and the semiconductor layer has a width substantially inversely proportional to one of the set of film thickness ratios corresponding to the each cell.

19. The method of claim 15, wherein the second set of cells includes a number of N cells having respective widths Wₗ to W_{N}, the widths W₁ to W_{N} satisfy an equation:
W₁+W₂+. . . , +Wᵢ+. . . +W_{N-1}W_{N}=N×W₀, N being an integer
where Wᵢ is the width of one of the number of N cells having a maximum film thickness ratio, and W₀ is the width of a cell free from the concern of film thickness distribution.

20. The method of claim 19, wherein the widths of W₁ to W_{N} correspond to a set of film thickness ratios R₁ to R_{N} and satisfy an equation:
Wᵢ(1/R₁+1/R₂+. . . +1+. . .+1/R_{N-1}+1/R_{N})=N×W₀
where R₁ equals 1, the maximum film thickness ratio, which corresponds to the width Wᵢ.
